(19) United States
(12) Patent Application Publication
(10) Pub. No.: US 2025/0273524 A1
(43) Pub. Date: Aug. 28, 2025

(54) INSULATION FOR MAGNETIC-MOLDING COMPOUND (MMC) MODULE

(71) Applicant: TEXAS INSTRUMENTS INCORPORATED, Dallas, TX (US)

(72) Inventors: Anton WINKLER, San Jose, CA (US); Hidetoshi INOUE, Oyama-Shi (JP); Kenji OTAKE, Karuizawa (JP)

(21) Appl. No.: 18/050,458

(22) Filed: Oct. 27, 2022

(51) Int. Cl. H01L 23/29; H01L 21/48; H01L 21/56; H01L 23/31; H01L 23/495

(52) U.S. Cl. CPC H01L 23/295; H01L 21/4825; H01L 21/565; H01L 23/3107; H01L 23/49503; H01L 23/4952; H10D 1/20

(57) ABSTRACT

A module includes: an integrated circuit (IC) die; a leadframe having contact pads; solder elements coupled between the IC die and the contact pads; an insulative layer between the solder elements; and magnetic-molding compound (MMC) filler between the IC die and the leadframe.

### BACKGROUND

Many integrated circuits (IC) are designed for use with external components. For example, an IC may include contact pads to couple IC circuitry to external ICs or passive components (e.g., resistors, capacitors, and/or inductors). To enhance energy storage of an inductor, a magnetic core may be used. In a conventional approach, a module having an IC die and an external inductor uses magnetic-molding compound (MMC) filler to form the magnetic core of the external inductor. However, some of the metallic particles of the MMC filler may result in undesirable leakage current between the IC die and other components or metallic contacts of the module.

### SUMMARY

In an example embodiment, a module comprises: an integrated circuit (IC) die; a leadframe having contact pads; solder elements coupled between the IC die and the contact pads; an insulative layer between the solder elements; and magnetic-molding compound (MMC) filler between the IC die and the leadframe.

In another example embodiment, a switching converter device comprises: an IC die including switching converter components; a leadframe having contact pads; solder elements coupled between the IC die and the contact pads; and an insulative layer between the solder elements. The switching converter device also comprises a coil having a core and first and second ends. The first end is coupled to a first solder element of the solder elements and a respective contact pad of the contact pads. The second end is coupled to a second solder element of the solder elements and a respective contact pad of the contact pads. The switching converter device also comprises magnetic-molding compound (MMC) filler in the core and between the IC die and the leadframe.

In yet another example embodiment, a method of manufacturing a module comprises: obtaining an IC die; obtaining a leadframe having contact pads; obtaining a coil having a core and first and second ends; adding an insulative layer to partially cover the contact pads; adding solder elements to exposed portions of the contact pads; and adding magnetic-molding compound (MMC) filler in the core and between the IC die and the leadframe.

### BRIEF DESCRIPTION OF THE DRAWINGS

FIG. 1 is a perspective view showing a module in accordance with an example embodiment.

FIGS. 2A-2H are cross-sectional views showing assembly of the module of FIG. 1 in accordance with an example embodiment.

FIGS. 3A and 3B are top view of insulation layer layout options in accordance with different example embodiments.

FIG. 4 is cross-sectional view showing layers of the module of FIG. 1 in accordance with an example embodiment.

FIG. 5A is a diagram showing MMC resistivity for a module without an insulative layer in accordance with a conventional approach.

FIG. 5B is a diagram showing MMC resistivity for a module with an insulative layer in accordance with an example embodiment.

### DETAILED DESCRIPTION

The same reference numbers or other reference designators are used in the drawings to designate the same or similar (either by function and/or structure) features.

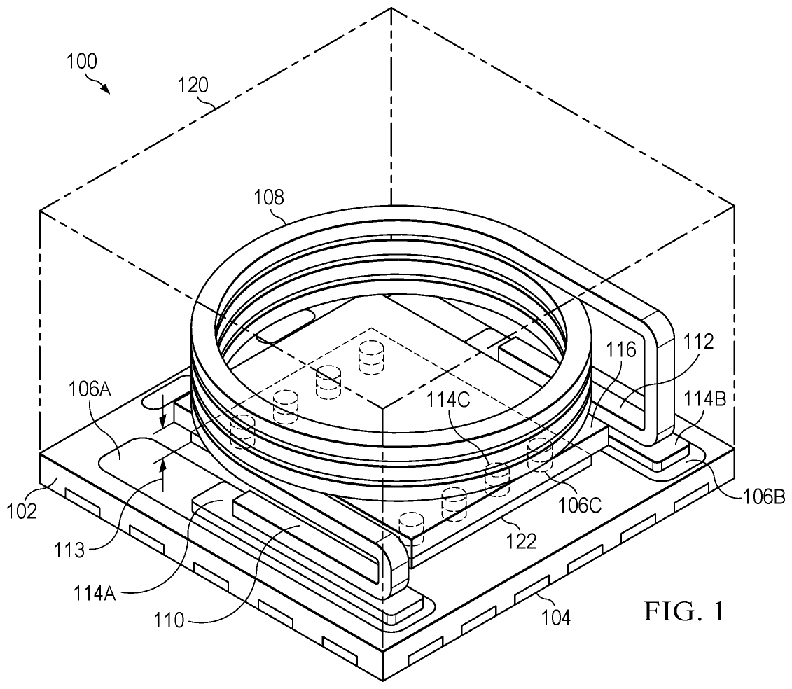

FIG. 1 is a perspective view showing a module 100 in accordance with an example embodiment. In the example of FIG. 1, the module 100 includes a leadframe 102 having conductive channels 104 and contact pads, including contact pads 106A and 106B and a set of contact pads 106C. In some example embodiments, the leadframe 102 is a routable leadframe (RLF), in which the conductive channels 104 relative to the contact pads 106A and 106B and the set of contact pads 106C are routable during fabrication of the leadframe 102. In the example of FIG. 1, the contact pad 106A couples to a first end 110 of a coil 108. The contact pad 106B coupled to a second end 112 of the coil 108. The set of contact pads 106C couple to respective contacts (not shown) of an IC die 116 included with the module 100.

In the example of FIG. 1, the module 100 also includes solder elements 114A and 114B and a set of solder elements 114C. Specifically, the solder element 114A is coupled between the contact pad 106A and the first end 110 of the coil 108. The solder element 114B is coupled between the contact pad 106B and the second end 112 of the coil 108. The set of solder elements 114C are coupled between the set of contact pads 106C and respective contacts of the IC die 116. As needed, the solder elements 114A and 114B, and the set of solder elements 114C may be supplemented using conductive leads (e.g., conductive leads 214 in FIGS.) to extend the conductive connection between the contact pads 106A and 106B and the coil 108 and/or to extend the conductive connection between the set of contact pads 106C and the IC die 116.

In the example of FIG. 1, there is a gap 113 between the leadframe 102 and the IC die 116, where the gap 113 is filled with a magnetic-molding compound (MMC) filler 120. The MMC filler 120 also fills a core of the coil 108. Without limitation, the MMC filler 120 forms a three-dimensional housing (e.g., a rectangular or cubic prism) around all other components of module 100 except the leadframe 102, which forms the base of the module 100. In some example embodiments, the thickness of the gap 113 is selected based on a target gap that limits MMC filler particle size between the IC die 116 and the leadframe 102 to less than a threshold particle size. In some example embodiments, the target gap between the IC die 116 and the leadframe 102 is achieved by adding an insulative layer 122 to the leadframe 102 in the area of the set of contact pads 106C. Additionally or alternatively, an insulative layer could be added to IC die 116 so that the gap 113 is less than the target gap. In either case, the thickness of the insulative layer 122 limits the thickness of the MMC filler 120 between the IC die 116 and the leadframe 102.

Without limitation, an example threshold particle size is 25 um. In such case, the target gap between the IC die 116 and the leadframe 102 will be 25 um. In this example, if the gap 113 between the set of contact pads 106C of the leadframe 102 and IC die 116 is 40 um, a 15 um thickness for the insulation layer 122 achieves the target gap. With the module 100, the MMC filler 120 improves the energy storage capacity of the coil 108. By insulating the set of contact pads 106C using the controlling the gap 113 and thus the thickness of the MMC filler 120 between the leadframe 102 and IC die 116, leakage current is reduced compared to a conventional approach.

In an example scenario, MMC filler particles may increase leakage current between ground (GND) of the IC die 116 and input voltage (VIN) contact pads (e.g., the set of contact pads 106C) of the leadframe 102. Leakage current over time may cause defects such as early failure of a module (e.g., the module 100). In some example embodiments, leakage current is suppressed by increasing insulation of the IC die 116 and/or contact pads (e.g., the set of contact pads 106C) of the leadframe 102. Gap reduction (between the IC die 116 and the leadframe 102) or other MMC filter particle size control options may also help suppress leakage current.

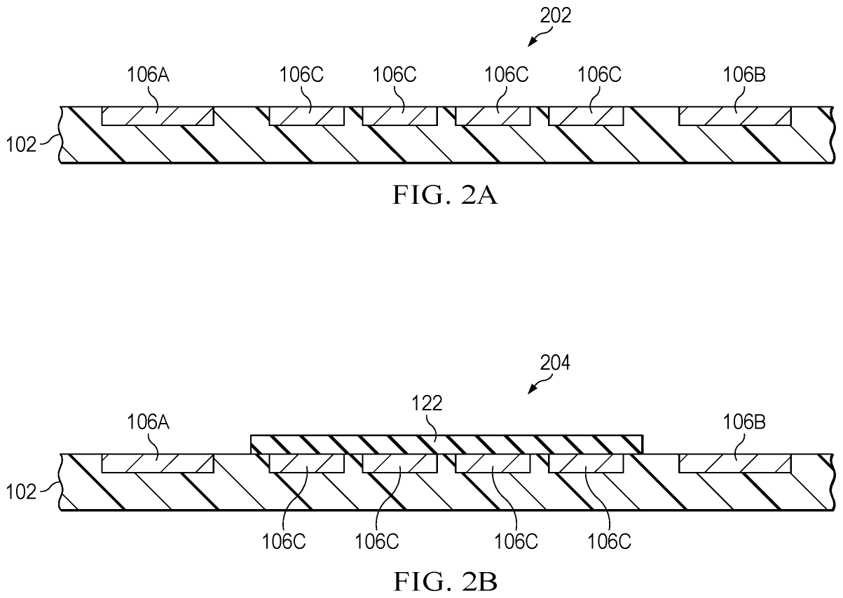

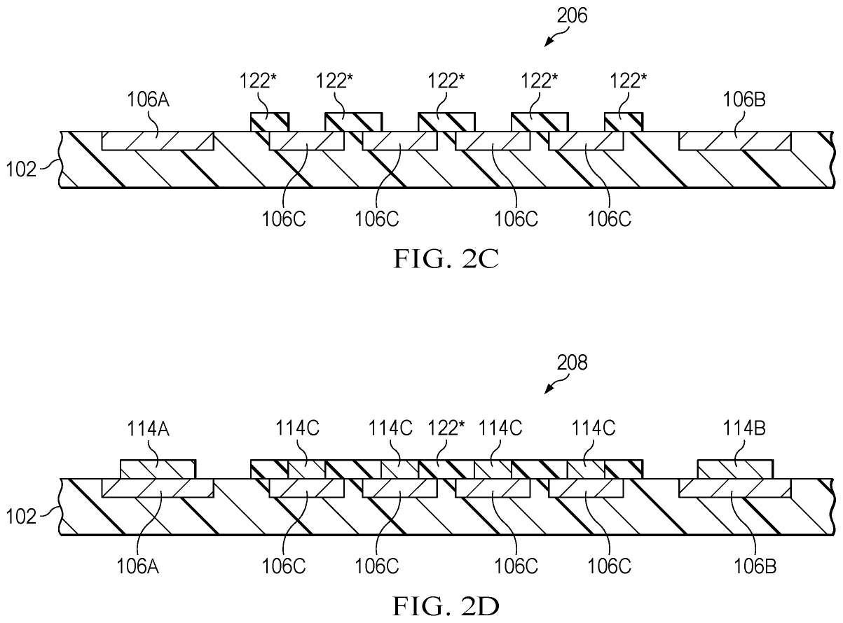

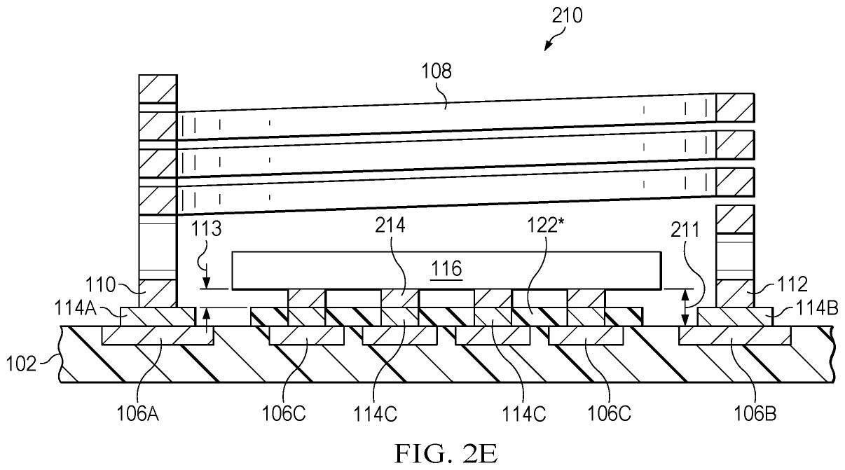

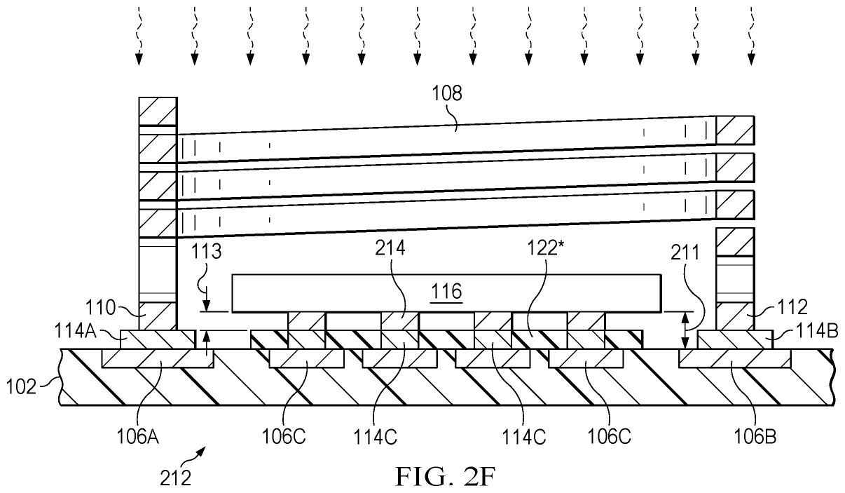

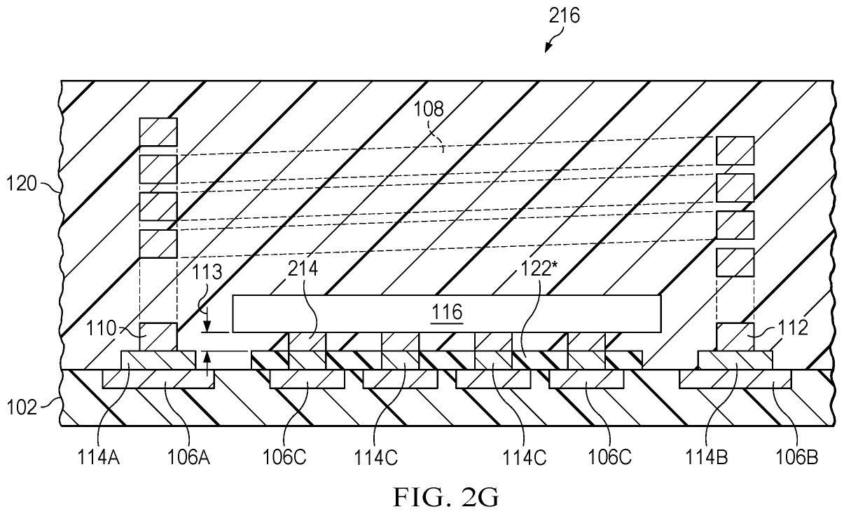

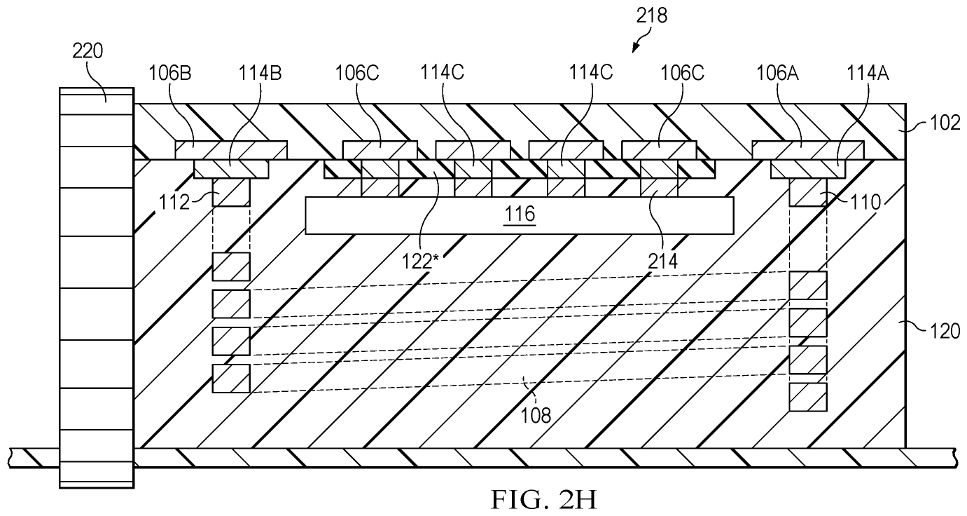

FIGS. 2A-2H are cross-sectional views 202, 204, 206, 208, 210, 212, 216, and 218 showing assembly of the module 100 of FIG. 1 in accordance with an example embodiment. In the cross-sectional view 202 of FIG. 2A, the leadframe 102 is prepared. In some example embodiments, preparing of the leadframe 102 includes adding and/or routing conductive channels such as the conductive channels 104 in FIG. 1. As shown, the leadframe 102 includes contact pads 106A and 106B, and the set of contact pads 106C. During preparation of the leadframe 102, the position of the contact pads 106A and 106B, and the set of contact pads 106C is selected and/or the connection of the contact pads 106A and 106B, and the set of contact pads 106C to respective conductive channels is performed.

In the cross-sectional view 204 of FIG. 2B, the insulative layer 122 is applied to the leadframe 102. In some example embodiments, the insulative layer 122 is applied so that it initially covers the set of contact pads 106C without covering the contact pads 106A and 106B. As another option, the insulative layer 122 may initially cover the contact pads 106A and 106B as well as the set of contact pads 106C. The thickness of the insulative layer 122 is selected to achieve a target insulation and/or a target gap between the leadframe 102 (with the insulative layer 122) and the IC die 116.

In the cross-sectional view 206 of FIG. 2C, the insulative layer 122 is modified, resulting in a modified insulative layer 122*. As shown, the modified insulative layer 122* at least partially exposes the set of contact pads 106C, while insulating remaining portions of the set of contact pads 106C. In some example embodiments, modified insulative layer 122* is based on application of an etching process or another targeted material removal process to the insulative layer 122.

In the cross-sectional view 208 of FIG. 2D, the solder elements 114A and 114B and a set of solder elements 114C are applied. Specifically, the solder element 114A is applied to the exposed portion of the contact pad 106A. The solder element 114B is applied to the exposed portion of the contact pad 106B. The set solder elements 114C are applied to the exposed portions of the set contact pads 106C.

In the cross-sectional view 210 of FIG. 2E, the IC die 116 and the coil 108 are positioned. Also, a set of conductive leads 214 (e.g., conductive posts) are positioned between set of solder elements 114C and the IC die 116. After positioning the coil 108, the first end 110 of the coil 108 is aligned with the solder element 114A and contact pad 106A, while the second end 112 of the coil 108 is aligned with the solder element 114B and contact pad 106B. Also, the set of solder elements 114C as well as contacts of the IC die 116 will be aligned with the conductive leads 214. The cross-sectional view 210 also shows reduction of gap thickness from an initial gap 211 to the gap 113 due to the modified insulative layer 122* being used.

In the cross-sectional view 212 of FIG. 2F, solder reflow is performed by heating the module components. The solder reflow process results in: the contact pad 106A being coupled to first end 110 of the coil 108 by the solder element 114A; the contact pad 106B being coupled to second end 112 of the coil 108 by the solder element 114B; the set of contact pad 106C being coupled to the IC die 116 by the set of solder element 114C and the set of conductive leads 214; and/or other solder connections of the module being completed.

In the cross-sectional view 216 of FIG. 2G, the MMC filler 120 is applied. The MMC filler 120 is applied, for example, by using a mold (not shown) to form a three-dimensional housing (e.g., a rectangular or cubic prism) around all other components of module 100 except the leadframe 102, which forms the base of the module 100. For example, the MMC filler 120 may initially flow or be in a liquid state before hardening into a predetermined shape based on the mold used. After MMC filler application is complete, the IC die 116 is separated from the leadframe 102 by the gap 113 whose thickness (and related thickness of the MMC filler 120 in the gap 113) is determined in part by a thickness of the modified insulation layer 122*.

In the cross-sectional view 218 of FIG. 2H, dicing operations are performed by a dicer 220 to separate the module 100 from a printed circuit board (PCB) or other leadframe assembly. In some example embodiments, many such modules are assembled together before the dicing operations are performed. After the dicing operations, the module 100 is complete. As desired, the module 100 is subsequently provided to customers or otherwise coupled to related circuitry to provide a desired function (e.g., switching converter operations).

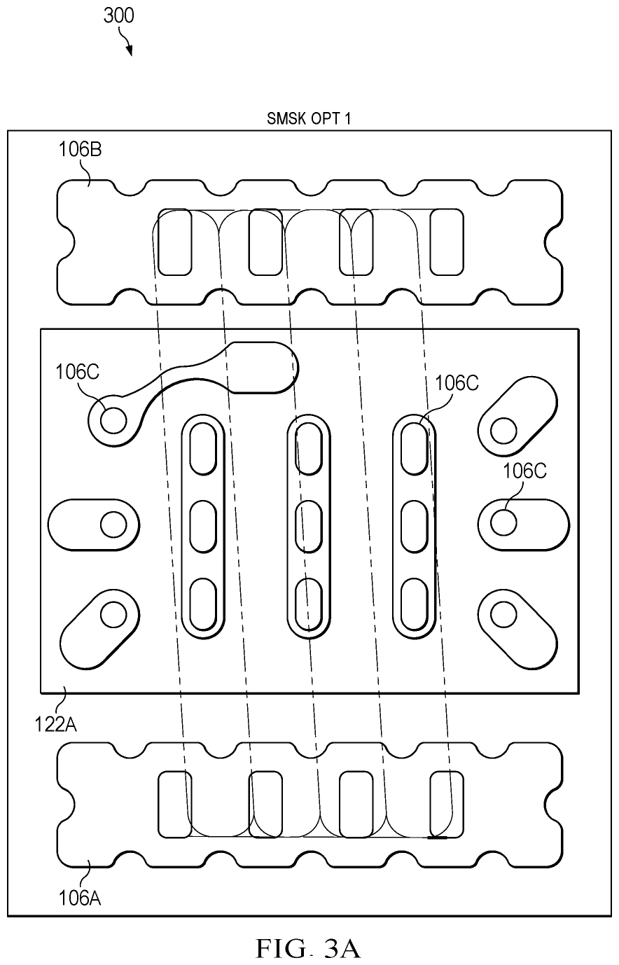

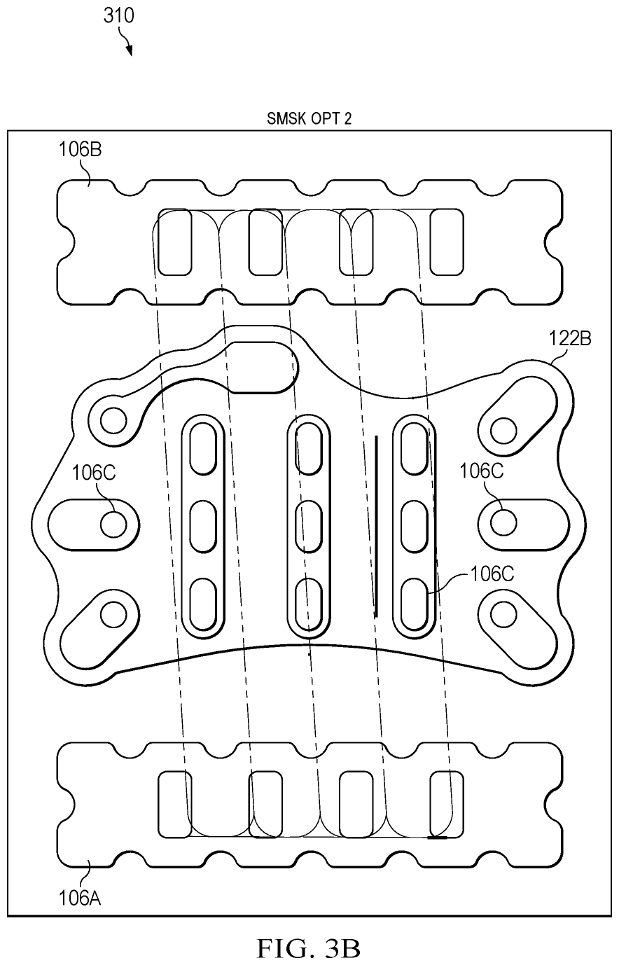

FIGS. 3A and 3B are top views 300 and 310 of insulation layer layout options in accordance with different example embodiments. In the top views 300 and 310, the contact pads 106A and 106B, and the set of contact pads 106C are represented. As shown, the layouts for a first insulation layer 122A and a second insulation layer 122B may vary. More specifically, the first insulation layer 122A in FIG. 3A has a rectangle layout (e.g., a geometric shape) that includes the set of contact pads 106C, while the second insulation layer 122B in FIG. 3B has an amorphous layout (e.g., a non-geometric shape) that includes the set of contact pads 106C. The layout option of the first insulation layer 122A may be selected, for example, to simplify application of an insulation layer to a leadframe to reduce costs. The layout option of the second insulation layer 122B may be selected, for example, to customize application of an insulation layer to a MMC module scenario (e.g., to reduce delamination between the insulation layer and MMC filler).

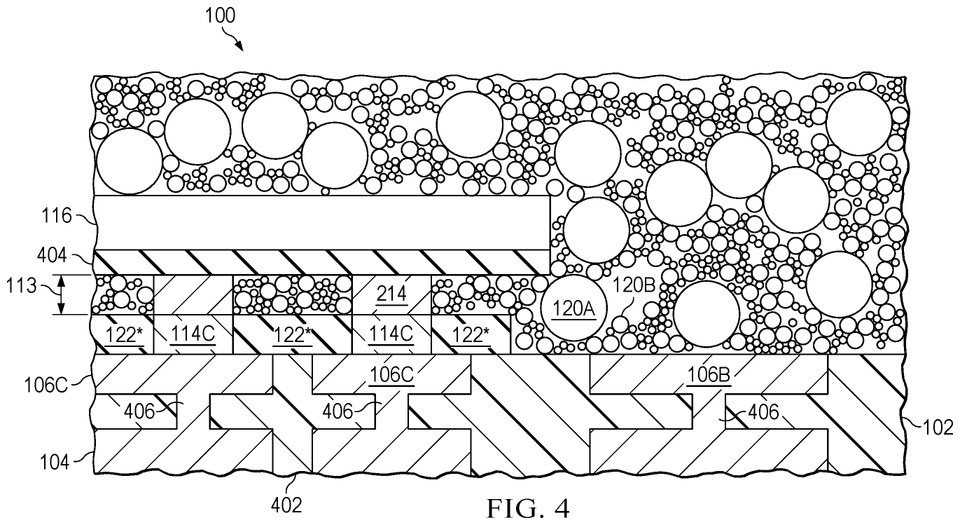

FIG. 4 is cross-sectional view showing layers of the module 100 of FIG. 1 in accordance with an example embodiment. As shown, the layers of the module 100 include layers of the leadframe 102 such as: some of the conductive channels 104; some of the contact pads of the set of contact pads 106C; conductive material 406 between conductive channels 104 and respective contact pads of the set of contact pads 106C. Without limitation, the conductive channels 104, the conductive material 406, and the set of contact pads 106C are made from copper (Cu) or a copper alloy. In some example embodiments, the remaining layers or portion of the leadframe 102 include Ajinomoto Build-Up Film@ (ABF) 402.

In the example of FIG. 4, the leadframe 102 includes the modified insulative layer 122* over partially exposed portions of the set of contact pads 106C. In some example embodiments, the modified insulative layer 122* is a solder resist layer. The set of solder elements 114C couple to the exposed portions of the set of contact pads 106C. Other layers of the module 100 of FIG. 4 include the IC die 116, which may include circuitry layers (not shown) and a polyimide (PI) layer 404 for additional insulation. Between the IC die 116 and the solder elements 114C are the conductive leads 214. In some example embodiments, the conductive leads 214 are copper posts.

In the example of FIG. 4, MMC filler is represented using a first set of MMC filler particles 120A and a second set of MMC filler particles 120B. As shown, the MMC filler particles of the second set of MMC filler particles 120B are smaller than the MMC filler particles of the first set of MMC filler particles 120A. Due to the modified insulative layer 122*, the gap 113 between the leadframe 102 and the IC die 116 is limited such that only the second set of MMC filler particles 120B fill the gap 113 (the first set of MMC filler particles 120A are too large to fit in the gap). By adjusting a thickness of the modified insulative layer 122*, the gap 113 is adjustable. The modified insulative layer 122* also limits exposure of the contact pads 106C. With the modified insulative layer 122*, the PI layer 404, and/or the second set of MMC filler particles 120B in the gap 113 between the leadframe 102 and the IC die 116, leakage current is reduced compared to a conventional approach.

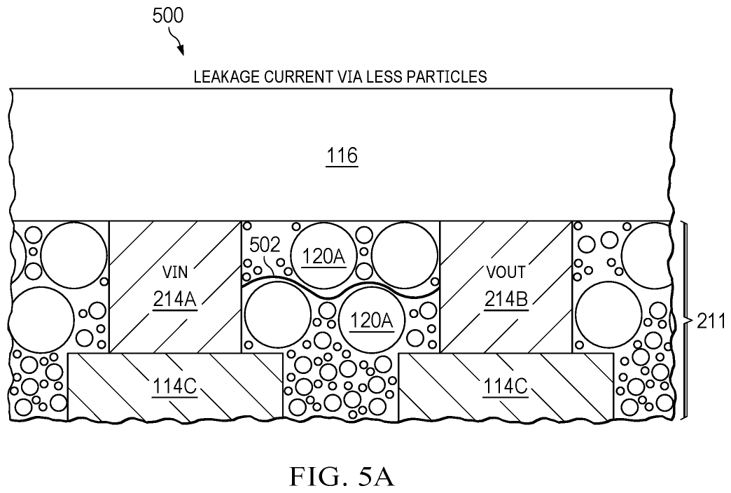

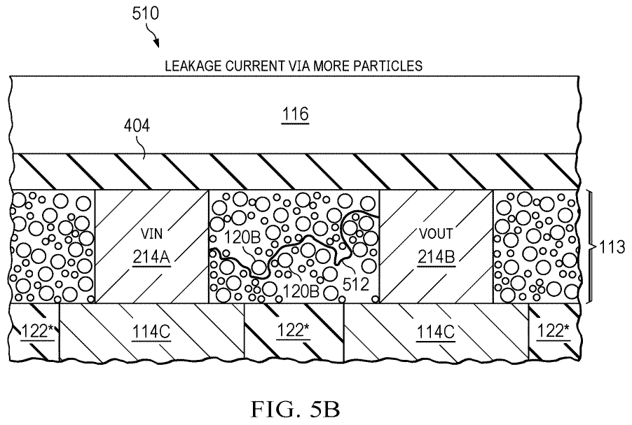

FIG. 5A is a diagram 500 showing a leakage current path 502 for a module without an insulative layer (e.g., the insulative layer 122 of FIGS. 1 and 2, or the modified insulative layer 122* of FIGS. 2 and 4) in accordance with a conventional approach. As shown in the diagram 500 of FIG. 5A, the leakage current path 502 flows between a first conductive lead 214A and a second conductive lead 214B using some of the first set of MMC filler particles 120A, resulting in a shorter leakage current path (compared to the leakage current path 512 in FIG. 5B). This is due, at least in part, to the initial gap 211 being larger than the size of the first set of MMC filler particles 120A. In the example of FIG. 5A, the first conductive lead 214A carries an input voltage (VIN) and the second conductive lead 214B carries an output voltage (VOUT) (e.g., related to a switching converter).

FIG. 5B is a diagram 510 showing a leakage current path 512 for a module (e.g., the module 100 of FIGS. 1, 2, and 4) having an insulative layer in accordance with an example embodiment. As shown in the diagram 510 of FIG. 5B, the leakage current path 512 flows between the first conductive lead 214A and the second conductive lead 214B using some of the second set of MMC filler particles 120B, resulting in a longer leakage current path (compared to the leakage current path 502 in FIG. 5A). In the example of FIG. 5B, the addition of the modified insulative layer 122* and the PI layer 404 provides insulation and limits the size of MMC filler particles in the gap 113 between to the second set of MMC filler particles 120B (the second set of MMC filler particles 120A are avoided in the gap 113). By adding insulative layers and/or limiting MMC particle size as in the example of FIG. 5B, leakage current is reduced

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, unless otherwise stated, “about,” “approximately” or “substantially” preceding a parameter means being within +/−10 percent of that parameter.

Modifications are possible in the described embodiments, and other embodiments are possible, within the scope of the claims.

What is claimed is:

1. A module, comprising:
an integrated circuit (IC) die;
a leadframe having contact pads;
solder elements coupled between the IC die and the contact pads;
an insulative layer between the solder elements; and
magnetic-molding compound (MMC) filler between the IC die and the leadframe.

2. The module of claim 1, wherein a thickness of the MMC filler between the IC die and the leadframe is limited by a thickness of the insulative layer.

3. The module of claim 2, wherein the thickness of the insulative layer is based on a target gap between the IC die and the leadframe.

4. The module of claim 3, wherein the target gap is selected to limit MMC filler particle size between the IC die and the leadframe to less than a threshold particle size.

5. The module of claim 1, wherein the insulative layer comprises solder resist.

6. The module of claim 1, wherein the insulative layer partially exposes the contact pads.

7. The module of claim 1, wherein the insulative layer has a layout based on an outline of the contact pads.

8. The module of claim 1, further comprising a coil having a first end and a second end, the first end coupled to a first solder element of the solder elements and a respective contact pad of the contact pads, the second end coupled to a second solder element of the solder elements and a respective contact pad of the contact pads, wherein a core of the coil includes the MMC filler.

9. The module of claim 1, wherein the IC die includes switching converter components.

10. A switching converter device, comprising:
an integrated circuit (IC) die including switching converter components;
a leadframe having contact pads;
solder elements coupled between the IC die and the contact pads;
an insulative layer between the solder elements;
a coil having a core and first and second ends, the first end coupled to a first solder element of the solder elements and a respective contact pad of the contact pads, the second end coupled to a second solder element of the solder elements and a respective contact pad of the contact pads; and
magnetic-molding compound (MMC) filler in the core and between the IC die and the leadframe.

11. The switching converter device of claim 10, wherein a thickness of the MMC filler between the IC die and the leadframe is limited by a thickness of the insulative layer.

12. The switching converter device of claim 11, wherein the thickness of the insulative layer is based on a target gap between the IC die and the leadframe.

13. The switching converter device of claim 12, wherein the target gap is selected to limit MMC filler particle size between the IC die and the leadframe to less than a threshold particle size.

14. The switching converter device of claim 10, wherein the insulative layer comprises solder resist.

15. A method of manufacturing a module, the method comprising:
obtaining an integrated circuit (IC) die;
obtaining a leadframe having contact pads;
obtaining a coil having a core and first and second ends;
adding an insulative layer to partially cover the contact pads;
adding solder elements to exposed portions of the contact pads; and
adding a magnetic-molding compound (MMC) filler in the core and between the IC die and the leadframe.

16. The method of claim 15, further comprising selecting a thickness of the insulative layer based on a target gap between the IC die and the leadframe.

17. The method of claim 16, further comprising selecting the target gap between the IC die and the leadframe to limit MMC filler particle size to less than a threshold particle size.

18. The method of claim 15, wherein adding the insulative layer comprises:
adding solder resist over the contact pads; and
etching the solder resist to partially expose the contact pads.

19. The method of claim 15, further comprising adding a polyimide (PI) layer to a side of the IC die that will face the leadframe.

20. The method of claim 19, further comprising heating the module to reflow the solder elements before adding the MMC filler.
